(19) United States
(12) Patent Application Publication
(10) Pub. No.: US 2005/0266685 A1
(43) Pub. Date: Dec. 1, 2005

(54) Method and apparatus for controlling a semiconductor fabrication temperature

(76) Inventors: Minoru Nakano, Tokyo (JP); Masaaki Ueno, Tokyo (JP); Kazuo Tanaka, Tokyo (JP)

Correspondence Address: KATTEN MUCHIN ROSENMAN LLP, 575 MADISON AVENUE, NEW YORK, NY, 10022-2585, US

(21) Appl. No.: 11/153,223

(22) Filed: Jun. 15, 2005

Related U.S. Application Data
(63) Continuation-in-part of application No. 09/675,220, filed on Sep. 29, 2000, now abandoned.

(30) Foreign Application Priority Data
Jan. 28, 2000 (JP) 2000-019934

(51) Int. Cl. H01L 21/44

(52) U.S. Cl. 438/660

(57) ABSTRACT

In a method for controlling temperatures in a semiconductor manufacturing apparatus including a reaction chamber and a plurality of heating sources, a set of power ratios to be fed to the heating sources is determined for each of two or more selected temperatures. Then, a temperature of the reaction chamber is controlled by performing power control on the heating sources based on at least one set of power ratios obtained.

### CROSS REFERENCE TO RELATED APPLICATION

This application is a continuation-in-part application of U.S. application Ser. No. 09/675,220 filed on Sep. 29, 2000.

### FIELD OF THE INVENTION

The present invention relates to a semiconductor manufacturing method and apparatus; and, more particularly, to a method and apparatus for use in controlling processing temperatures during the fabrication of semiconductor devices.

### BACKGROUND OF THE INVENTION

In a conventional single wafer epitaxial growth apparatus for processing substrates such as silicon wafers one at a time, a substrate is loaded into a processing chamber of the growth apparatus and heated upto a predetermined processing temperature while supplying reaction gases to form a thin film on top of the substrate.

In such a single wafer epitaxial growth apparatus, it is crucial to control temperatures inside the processing chamber appropriately. In detail, temperature uniformity throughout a wafer is required during maintaining a constant temperature of the wafer and also during heating/cooling processes thereof; and the accuracy of the temperature control greatly affects the quality of a semiconductor device to be manufactured. The temperature uniformity throughout the wafer surface in such a single wafer epitaxial growth apparatus is more crucial than in a batch-type thermal processing apparatus such as a vertical-type thermal diffusion furnace.

One of conventional techniques for controlling uniform temperatures inside a thermal processing chamber is described in a Japanese Patent Laid-Open Publication No. 64-8225. According to the prior art reference above, the processing chamber is provided with electric heaters for heating a center portion and an edge portion of a body to be heated and the heaters are controlled based on the differences between a target temperature and actual temperatures of the body measured by employing a temperature sensor. In the conventional method, a power fed to an electric heater for heating the edge portion of the body is kept to be less than that provided to an electric heater for heating the center portion.

Since, however, the conventional temperature control method described above does not provide the temperature uniformity during the heating/cooling processes, which is strictly required in the single wafer epitaxial growth apparatus, the conventional method may not be suitably employed therein to obtain the desired temperature uniformity which in turn gives rise to a required device quality.

Further, it is not desirable to install a number of temperature sensors in the single wafer epitaxial growth apparatus and monitor temperatures at various regions of a wafer during a process in order to control processing temperatures since the installation of the temperature sensors itself might cause contamination problems during the process due to substances which can be generated therefrom.

Accordingly, it is needed to accomplish the required temperature uniformity over a wafer in the single wafer epitaxial growth apparatus without measuring temperatures at various regions of the wafer during a process.

### SUMMARY OF THE INVENTION

It is, therefore, a primary object of the present invention to provide a method for controlling temperatures in a semiconductor manufacturing apparatus to achieve the desired temperature uniformity over a semiconductor substrate to thereby improve the quality of a semiconductor device fabricated. In accordance with the present invention, temperature uniformity throughout the substrate is provided over any preset temperature range by simply monitoring temperatures at one or two predetermined locations in a processing chamber of the semiconductor manufacturing apparatus without monitoring the temperatures at various regions of the substrate.

Another object of the present invention is to provide a semiconductor manufacturing apparatus employing the inventive temperature control method described.

Still another object of the invention is to provide a semiconductor manufacturing method employing the inventive temperature control method.

In accordance with a preferred embodiment of the present invention, there is provided a method for controlling temperatures in a semiconductor manufacturing apparatus including a reaction chamber and a plurality of heating sources, comprising the steps of: determining a set of power ratios to be fed to the heating sources for each of at least one selected temperature by using plural temperature sensors; and controlling a given temperature by performing power control on the heating sources based on at least one set of power ratios obtained in the determining step by using one or more temperature sensors, and said temperature controlling step is carried out by using a P(proportional), an I(integral) and a D(derivative) operation outputs and power ratios corresponding to the given temperature, the power ratios corresponding to the given temperature being determined based on one or two sets of power ratios determined in the determining step, and wherein a controlled power output for a heating source is determined by multiplying the P, the D and the I operation outputs by a power ratio during processing a wafer and is determined by multiplying the power ratio only by the I operation output when loading a wafer into the reaction chamber.

In accordance with another preferred embodiment of the present invention, there is provided a method for controlling temperatures in a semiconductor manufacturing apparatus including a reaction chamber and a plurality of heating sources, comprising the steps of: determining a set of power ratios to be fed to the heating sources for each of at least one selected temperature by using plural temperature sensors; and controlling a given temperature by performing power control on the heating sources based on at least one set of power ratios obtained in the determining step by using one or more temperature sensors, wherein the number of temperature sensors used in the determining step is greater than the number of temperature sensors used in the controlling step, and wherein the set of power ratio, based on which the power control is performed, is changed at an estimated time of reaching a target temperature.

In accordance with still another preferred embodiment of the present invention, there is provided a method for controlling temperatures in a semiconductor manufacturing apparatus including a reaction chamber and a plurality of heating sources, comprising the steps of: determining a set of power ratios to be fed to the heating sources for each of at least one selected temperature by using plural temperature sensors; and controlling a given temperature by performing power control on the heating sources based on at least one set of power ratios obtained in the determining step by using one or more temperature sensors, wherein the number of temperature sensors used in the determining step is greater than the number of temperature sensors used in the controlling step, and wherein the set of power ratio, based on which the power control is performed, is changed at an estimated time of reaching a target temperature when loading a wafer into the reaction chamber, while the set of power ratio, based on which the power control is performed, is changed at a time when a measured temperature reaches the target temperature during processing a wafer.

In accordance with another aspect of the present invention, there is provided a semiconductor device manufacturing method by using the temperature controlling method described above.

In accordance with still another aspect of the present invention, there is provided a temperature controlling apparatus by using the temperature controlling method described above.

In accordance with still another aspect of the present invention, there is provided a semiconductor manufacturing apparatus by using the temperature controlling method described above.

When an amount of heat being generated from the heating sources is equal to that being dissipated from the processing chamber, the total amount of heat remaining therein can be maintained constant and thus an overall thermal steady-state can be maintained. Even under the overall thermal steady-state, however, temperatures can vary at different regions of a wafer being processed and at various locations of the processing chamber.

Accordingly, in order to maintain a uniform temperature over the regions dissipating varying amounts of heat therefrom, a greater power should be supplied to a heating source for heating a region dissipating more heat. Therefore, a plurality of different regions to be controlled to have a uniform temperature are set and a power ratio capable of rendering a uniform temperature at the plurality of regions is determined in advance for each of predetermined various temperatures. By using these power ratios, temperatures across the wafer can be stabilized fast within a certain temperature range even after a temperature change, e.g., due to a heating/cooling process.

Through the use of the temperature control method described above, optimum power ratios for different regions can be determined by using target temperatures or measured temperatures obtained only from selected regions, without monitoring temperatures from all the regions to be controlled to have a uniform temperature; and, therefore, uniform temperature control over a surface of a substrate can be achieved even during a ramp-up/down process and a reaction process (e.g., deposition and etching).

### BRIEF DESCRIPTION OF THE DRAWINGS

The above and other objects and features of the present invention will become apparent from the following description of preferred embodiments given in conjunction with the accompanying drawings in which:

FIG. 1 illustrates a schematic side view of a processing chamber of a single wafer epitaxial growth apparatus in accordance with a preferred embodiment of the present invention;

FIG. 2 depicts a block diagram of a lamp controller in accordance with the preferred embodiment of the present invention;

FIG. 3 provides a flow chart for describing a method for controlling temperatures in accordance with a preferred embodiment of the present invention;

FIG. 4 is an exemplary power ratio table for a setting temperature of 500° C.;

FIG. 5 shows an exemplary power ratio table for a setting temperature of 700° C.;

FIG. 6 sets forth an exemplary target temperature profile of a wafer in accordance with a preferred embodiment of the present invention;

FIG. 7 represents temperature profiles controlled by using PID and PD-I power ratio control schemes in accordance with the preferred embodiment of the present invention;

FIG. 8 exemplifies temperature profiles controlled based on target and measured temperatures in accordance with the preferred embodiment of the present invention; and

FIG. 9 outlines an overall process for controlling temperatures inside the single wafer epitaxial growth apparatus in accordance with the preferred embodiment of the present invention.

### DETAILED DESCRIPTION OF THE PREFERRED EMBODIMENTS

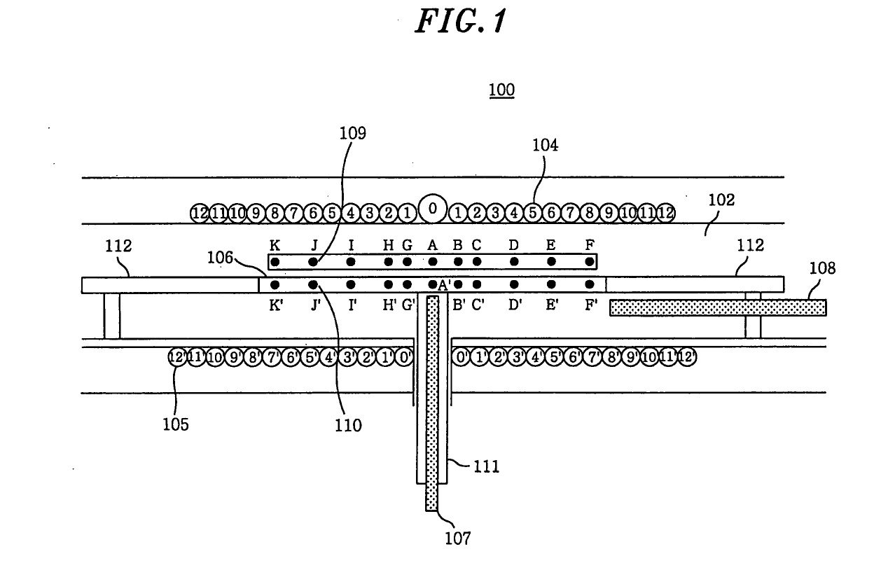

Referring to FIG. 1, there is illustrated a schematic side view of a processing chamber 100 of a single wafer epitaxial growth apparatus in accordance with a preferred embodiment of the present invention. In the processing chamber 100, a substrate such as a silicon wafer 103 is mounted in a reaction chamber 102 and heated to a predetermined temperature; and reaction gases are supplied thereinto, thereby forming a thin film on top of the wafer 103.

Heating sources are formed of two sets 104 and 105 of circle lamps of a ring shape installed outside the reaction chamber 102, one above and the other below the reaction chamber 102. The upper and the lower sets 104 and 105 of circle lamps respectively include a multiplicity of, e.g., 13, circle lamps represented by numerals 0 to 12 and 0′ to 12′ in small circles as shown in FIG. 1.

Most of the heat from each circle lamp are absorbed by the wafer 103, the reaction gases supplied into the reaction chamber 102 and a susceptor (e.g., SiC susceptor) 106 of a large heat capacity for supporting the wafer 103. The circle lamps 0-8 and 9-12 of the upper set 104 of circle lamps constitute a central zone and a peripheral zone, respectively. The circle lamps 0′ to 7′ and 8′-12′ of the lower set 105 of circle lamps constitute a central zone and a peripheral zone thereof, respectively.

A central temperature sensor 107 and a peripheral temperature sensor 108 are installed at a center portion and a periphery portion of the processing chamber 100, respectively. Upper temperature profile sensors 109 are installed at, e.g., eleven positions on a surface of the wafer 103 as indicated by A to K in FIG. 1; and lower temperature profile sensors 110 are installed at, e.g., eleven positions on a surface of the susceptor 106 as indicated by A′ to K′ in FIG. 1.

The sensors 109 and 110 are employed only during a power acquisition stage for determining power ratios to the circle lamps 0-12 and 0′-12′ in advance by measuring the temperatures at the predetermined positions, and thus are removed thereafter and are not used during an actual semiconductor processing stage, e.g., deposition and etching processes. The susceptor 106 is rotatably supported by a supporting member 111, center of the supporting member 111 functioning as a rotational axis. A fixed SiC ring die 112 is installed around the periphery of the susceptor 106. The processing chamber 100, the wafer 103, the susceptor 106, the supporting member 111 and the SiC ring die 112 have substantially circular shapes when viewed from top of the processing chamber 100.

In the processing chamber 100, there is installed the rotatable supporting member 111 at a center portion of the substrate and heat can be easily dissipated therethrough. Further, since there is a loading/unloading port (not shown) of the reaction chamber 102 at a peripheral portion thereof, heat can also be easily dissipated therethrough. It is undesirable to install many temperature sensors in view of space and contamination problems which might occur therefrom. Accordingly, by installing the temperature sensor 107 and 108 at the center portion and the peripheral portion where temperatures are unstable and by using the measured temperatures obtained therefrom in controlling processing temperatures, the number of temperature sensors can be minimized and the temperatures can be precisely controlled.

As is well known in the art, silicon becomes metallic and highly reactive at elevated temperatures to thereby readily form an oxide film on the surface thereof by the reaction with oxygen or moisture. Generally, a silicon wafer is prepared by slicing a silicon ingot, which is produced by dipping a seed crystal of silicon mounted on a rotating rod into a molten silicon contained in a quartz crucible and slowly cooling down the crystallized silicon while pulling out the rotating rod.

Since a silicon wafer produced in a manner described above normally has defects of about 10⁶/cm³ including, e.g., oxygen precipitate, voids and/or vacancies, an oxide film and such defects should be removed from the surface of the silicon wafer prior to an epitaxial growth. Accordingly, a silicon wafer is baked at a temperature of about 1000° C. or above in a high purity hydrogen gas. The oxide is removed by the thermal reaction below:
SiO₂(solid)+Si(solid) [symbol] 2SiO(gas).

Defects of the surface region of the Si wafer are removed and planarized by the high temperature reflow process and then an ideal single crystalline Si surface can be obtained. Si epitaxial growth is carried out by CVD (chemical vapor deposition) in a gaseous atmosphere composed of hydrogen gas and a Si-containing gas source, e.g., silicon tetrachloride (SiCl₄), trichlorosilane (TCS: SiHCl₃), dichlorosilane (DCS: SiH₂Cl₂) and monosilane (SiH₄).

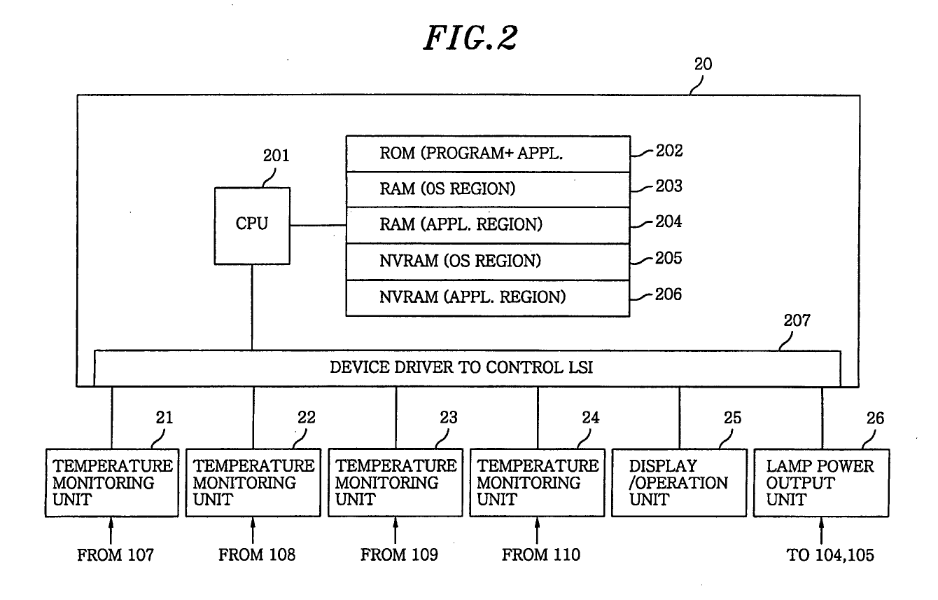

FIG. 2 is a block diagram of a lamp controller 20 in accordance with the preferred embodiment of the present invention. The lamp controller 20 controls powers to be supplied to the heating sources 0-12 and 0′-12′ in the upper and lower sets 104 and 105 of circle lamps. The lamp controller 20 includes a CPU 201, a ROM 202 for OS and application programs, a RAM 203 for OS programs, a RAM 204 for application programs, a NVRAM 205 for OS programs, a NVRAM 206 for application programs and a device driver 207 for controlling communication control LSI circuitry.

The device driver 207 is connected to temperature monitoring units 21 to 24, a display/operation unit 25 and a lamp power output unit 26 as shown in FIG. 2. The first temperature monitoring unit 21 monitors an output of the temperature sensor 107 installed at the center portion of the processing chamber 100. The second temperature monitoring unit 22 monitors an output of the temperature sensor 108 installed at the periphery portion of the processing chamber 100. The third temperature monitoring unit 23 monitors outputs from the upper temperature profile sensors 109 for detecting temperatures of a surface of the wafer 103. The fourth temperature monitoring unit 24 monitors outputs of the lower temperature profile sensors 110 for detecting temperatures of a surface of the susceptor 106.

The lamp controller 20 reads temperatures detected from the temperature sensors 107 and 108 via the monitoring units 21 and 22 to thereby carry out power ratio control operation by comparing the temperatures detected at the temperature sensors 107 and 108 with a predetermined target temperature. Details of the power ratio control operation will be discussed hereinafter. The result of the power ratio control operation is periodically fed to the lamp power output unit 26 as a power ratio control output value (ranging from 0% to 100%) for each circle lamp.

In response to the power ratio control output values from the lamp controller 20, the lamp power output unit 26 outputs a power for each of the circle lamps 0-12 and 0′-12′ of the upper and lower sets 104 and 105. Monitored temperatures and power ratio control output values obtained are transmitted to the display/operation unit 25, enabling the real time control state to be provided to an operator.

The temperature monitoring units 21 to 24 convert analog temperature signals outputted from corresponding temperature sensors into digitized temperature signals and then send the digitized temperature signals to the lamp controller 20 through a digital communication channel. By using the digital communication channel, improved anti-noise, distortion and interference properties can be obtained in comparison with the analog communication.

Since a high speed operation is required in the monitoring units 21 and 22, the number of temperature sensors connected to each of the monitoring units 21 and 22 is limited to one. On the other hand, the temperature monitoring units 23 and 24 are not used in control operation during an actual device processing step but instead are merely used prior to the actual processing step in order to determine proper power ratios for the circle lamps capable of obtaining a uniform temperature at a surface of a wafer. Accordingly, high speed operation is not required in the temperature monitoring units 23 and 24, and, therefore, a plurality of, e.g., eleven, temperature sensors (11 channels) are connected thereto.

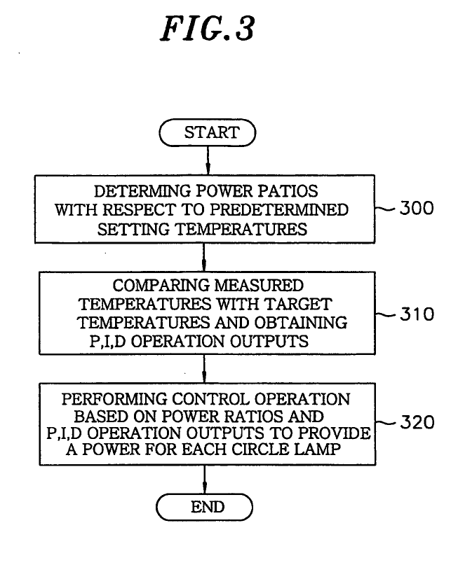

FIG. 3 is a flow chart describing a method for controlling temperatures in accordance with the preferred embodiment of the present invention. At step 300, a set of power ratios for the heating sources is determined for each of predetermined setting temperatures and stored as the power ratios thereof. Power ratio determination scheme will be described in further detail hereinafter.

Next, at step 310, measured temperatures from the temperature sensors 107 and 108 are compared with predetermined target temperatures of the wafer 103; and P(proportional), I (integral), D(derivative) operation outputs are obtained with respect to the central and the peripheral zones. For example, a temperature output PV1 measured at an instant from the central temperature sensor 107 is compared with a corresponding target temperature to provide P, I, D operation outputs of the central zone at that instant; and a temperature output PV2 obtained at that instant from the peripheral temperature sensor 108 is compared with the corresponding target temperature to generate P, I, D operation outputs of the peripheral zone at that instant. The P, I and D operation outputs determination scheme is well known in the art and, therefore, will not be described in detail for the sake of simplicity.

In the preferred embodiment shown in FIG. 1, the central zone corresponds to the regions where the circle lamps 0-8 of the upper set 104 of circle lamps and those 0′-7′ of the lower set 105 of circle lamps are located. The peripheral zone corresponds to the regions where the circle lamps 9-12 of the upper set 104 of circle lamps and those 8′-12′ of the lower set 105 of circle lamps are disposed.

Thereafter, at step 320, power ratio control operation is performed based on the P, I, D operation outputs obtained from step 310 and the power ratios predetermined at step 300, thereby determining a power ratio control output for each of the circle lamps of the upper and lower sets 104 and 105 of circle lamps. At the lamp power output unit 26, the power ratio control output is converted into a corresponding actual lamp power and the generated lamp power output is applied to a corresponding circle lamp.

A power ratio control output can be determined by using one of the two power ratio control schemes below:
(1) PID power ratio control:
   a controlled power for a circle lamp ═(PID operation output)*(corresponding power ratio to the circle lamp),
(2) PD-I power ratio control:
   a controlled power for a circle lamp ═(PD operation output)+((I operation output)* (corresponding power ratio to the circle lamp)).

The P and the D operation outputs can be greatly varied according to the temperature changes, while the I operation output is less affected by the temperature changes than the P and the D operation outputs. By combining these P, I and D operation outputs properly, the inner temperature of the reaction chamber 102 can reach to a uniform temperature fast through undergoing a substantially reproducible temperature change process. For instance, when there occurs a temperature change in a wafer loading process, a temperature profile reproducibility can be improved by using a proper combination of P, I, D operation outputs as will be discussed in further detail hereinafter.

The power ratio determination of step 300 can be carried out as follows. First, by using a dummy wafer or a process wafer, a power output for each of the lamps 0-12 and 0′-12′ is controlled by using the lamp controller 20 in such a way that temperatures detected by the temperature profile sensors on the surfaces of the wafer 103 and/or the susceptor 106 fall within a predetermined uniform temperature range, e.g., 498° C. to 502° C. around a corresponding setting temperature, e.g., 500° C. Power output ratios satisfying this condition is set as power ratios for the lamps 0-12 and 0′-12′ at the corresponding setting temperature; and at the same time, the temperature(s) sensed by the central temperature sensor 107 and/or the peripheral temperature sensor 108 is recorded and used later as a reference of the setting temperature during an actual device fabrication process.

This procedure is carried out for each of preset different setting temperatures appropriately selected within a temperature range to be used in a device fabrication process. A set of the obtained power ratios for each of the setting temperatures is registered as a power ratio table for that temperature. By using power ratio tables for a selected number of setting temperatures, memory capacity required for the storage thereof can be substantially reduced.

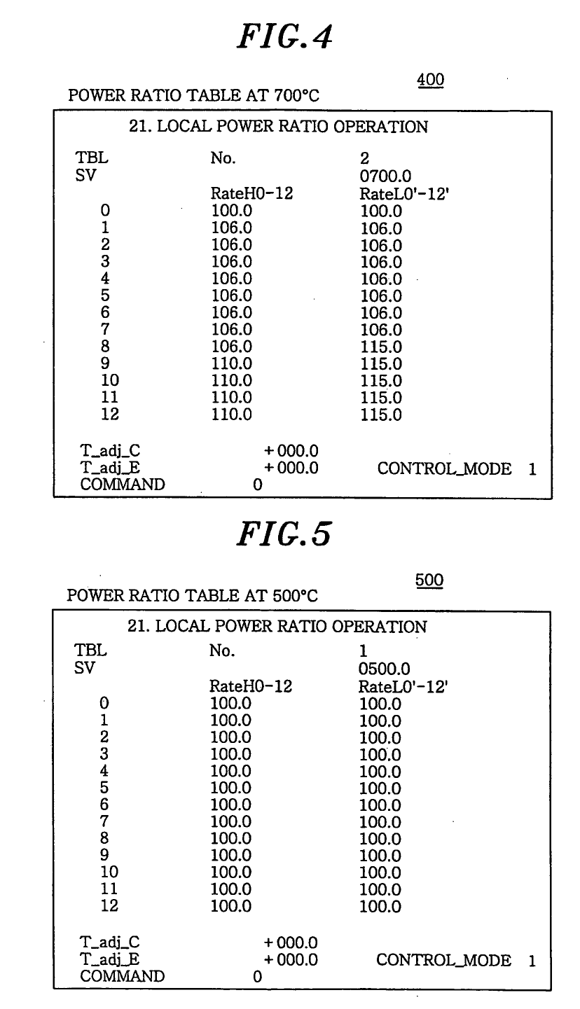

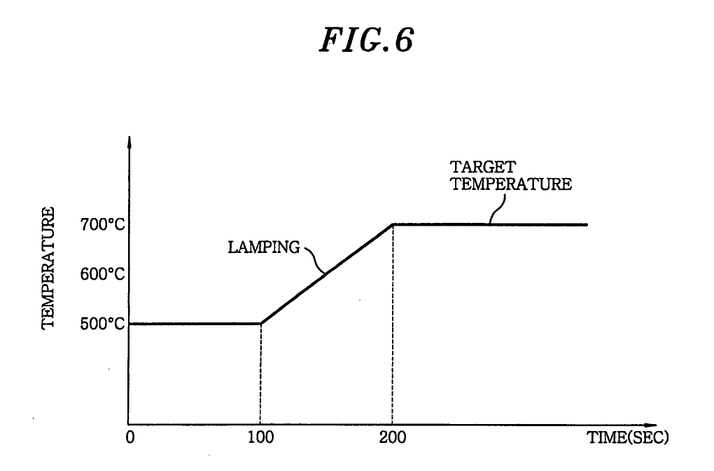

FIGS. 4 and 5 are exemplary power ratio tables for the setting temperatures of 500° C. and 700° C., respectively. In each table, TBL No. represents a power ratio table number; SV, a setting temperature at which power ratios are obtained; RateH0-12 and RateL0′-12′, power ratios corresponding to the upper circle lamps 0-12 and lower circle lamps 0′-12′, respectively.

A power ratio table can be selected by designating the table number. In the preferred embodiment of the present invention, however, a programmed power ratio table selection scheme is employed by which a corresponding power ratio table can be automatically selected according to a control temperature, the control temperature being one of a target temperature and a measured temperature by the central temperature sensor 107 or the peripheral temperature sensor 108.

In this method, one or more power ratio tables appropriate to the control temperature are selected among the power ratio tables established and then the power ratio control operation is performed by using the power ratios of the selected power ratio tables. A target temperature or a measured temperature is adaptively set as a control temperature by considering the temperature reproducibility as will be described in further detail hereinafter.

To be specific, if a target temperature is set as a control temperature, the selected power ratio table (i.e., a set of power ratios), based on which the power control is performed, is changed (i.e., switched to another table) at the approximated or estimated time of reaching the target temperature, which will be described in detail in following paragraphs. Otherwise, if a measured temperature is set as a control temperature, the selected power ratio table (i.e., a set of power ratios), based on which the power control is performed, is changed at a time when the measured temperature reaches the target temperature.

For instance, if there is one and only power ratio table registered for the single setting temperature of 500° C., the power ratios of the registered table are used for all control temperatures. If there exist two power ratio tables for the setting temperatures of 500° C. and 700° C., linearly interpolated power ratios of the registered power ratios are used for the control temperatures between 500° C. and 700° C. If a control temperature is 800° C., the power ratios of the setting temperature of 700° C. can be used for that temperature without interpolation or the power ratios for 800° C. can be obtained by extrapolation based on the power ratios of 500° C. and 700° C. The power ratio tables are stored in the NVRAM 205 shown in FIG. 2.

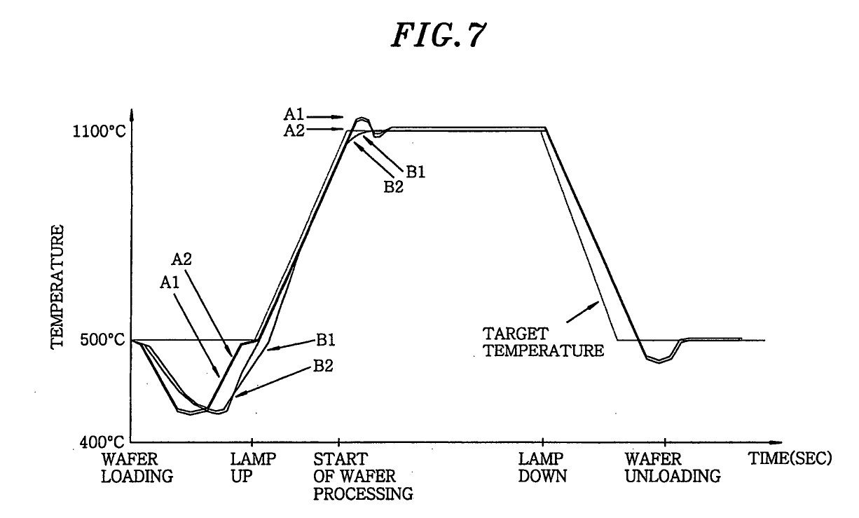

FIG. 6 sets forth an exemplary target temperature profile of the wafer 103. Power ratio control operation results carried out with reference to the target temperature profile shown in FIG. 6 based on the power ratio tables shown in FIGS. 4 and 5 will be described below. In this example, it is assumed that the power ratio tables are selected by using target temperatures. That is, in this example, an employed power ratio table is switched to a different table at an estimated point of time when the target temperature is expected to have been reached.

First, during 0 to 100 seconds, the power ratio table shown in FIG. 4 is used since the target temperature is 500° C. Assuming that P, I and D operation outputs are respectively 50%, 30% and −10% at the center zone and the PID power ratio control is employed, power ratio control outputs for the circle lamps 0-8 of the upper set 104 and those 0′-7′ of the lower set 105 all become 70% (=70% (PID operation output)*1.00 (power ratios)). When the PD-I power ratio control is employed, power ratio control outputs for the lamps 0-8 and 0′-7′ are also set to be 70% (=30% (I operation output)*1.00 (power ratios)+50% (P operation output)−10% (D operation output)).

Since the target temperatures are set to increase between 100 and 200 seconds as set forth in FIG. 6, corresponding power ratios vary with time accordingly. For instance, if the P, I and D operation outputs are same as above, power ratio control outputs for the target temperature of 600° C. at 150 seconds are obtained as follows. In other words, in this case, the set of power ratios, which is used, is switched after 150 seconds, when the temperature is expected to reach 600° C., or when the target temperature reaches 600° C. The proportional factor of 600° C. is ½ (=(600−500)/(700−500)) and PID operation output is 70% (=50%+30%−10%). If the PID power ratio control is employed, the control output of the upper lamp 0 becomes 70% (=70%* (1.00+1.00)/2); control operation outputs for the upper lamps 1-8 are 72.1% (=70%*(1.06+1.00)/2); that for the lower lamp 0′ is 70% (=70%*(1.00+1.00)/2); and those for the lower lamps 1′-7′ become 72.1% (=70%*(1.06+1.00)/2).

If the PD-I power ratio control is employed, the control outputs for the upper lamp 0 and the lower lamp 0′ become 70% (=30%*((1.00+1.00)/2))+50%−10%); and the control operation outputs for the upper lamps 1-8 and lower lamps 1′-7′ become 70.9% (=30%*((1.06+1.00)/2))+50%−10%).

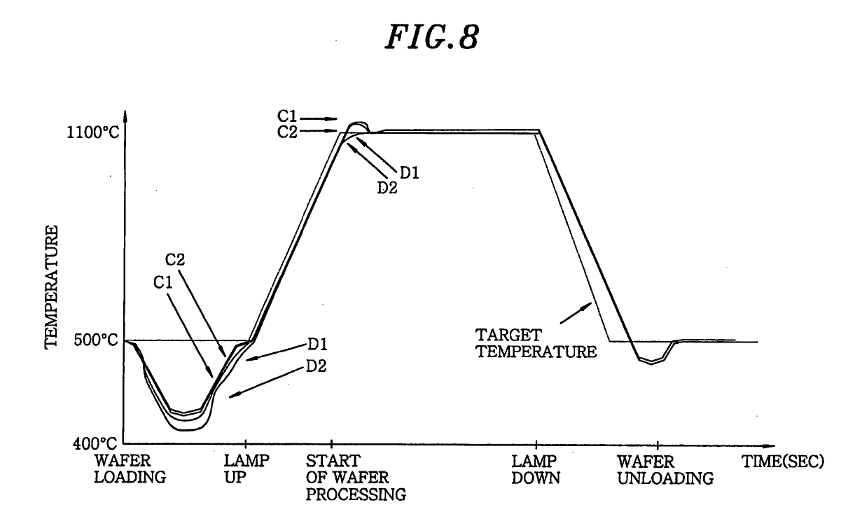

Power ratio control outputs for the peripheral zone can be obtained in a similar manner by using P, I, D operation outputs for the peripheral zone. The PID or PD-I power ratio control scheme can be adaptively employed depending on a state of the apparatus. For example, the PID power ratio control can be preferably used when a temperature is stable or during ramping-up and ramping-down stages where there is no external disturbance; and the PD-I power ratio control may be preferably employed when there is an external disturbance due to, e.g., wafer loading and unloading, as will be discussed with reference to FIG. 7.

Referring to FIG. 7, there are illustrated exemplary PID and PD-I power ratio control results obtained in accordance with the preferred embodiment of the present. In FIG. 7, the horizontal axis is a time axis illustrating sequential events of wafer loading, ramp-up, start of a wafer processing, ramp-down, wafer unloading; and the vertical axis represents temperatures.

In FIG. 7, a dotted line S represents target temperatures. The temperatures inside the reaction chamber 102 are basically controlled to follow this target temperature profile. The lines designated by reference signs A1 and A2 represent measured temperature profiles at the center zone obtained by performing the PD-I power ratio control twice; and the lines designated by reference signs B1 and B2 represent measured temperature profiles at the center zone obtained by performing the PID power ratio control twice.

As is apparent from FIG. 7, the PD-I power ratio control provides better reproducibility, i.e., less deviation between A1 and A2, in comparison with a PID power ratio control when an external disturbance, e.g., due to a wafer loading occurs.

An inner temperature of the reaction chamber 102 is greatly changed when there occurs a disturbance due to, e.g., gas input or loading of a wafer having a considerable thermal capacity. In this case, P and D operation outputs are greatly affected by the temperature change therein. Since, however, the I operation output is an integration output value, I operation output is affected far less than the P and D operation outputs. Therefore, when a power ratio is multiplied by only the I operation output, the control output can be less affected by the changes of the P and D operation values than in the case where the power ratio is multiplied by all the P, D and I operation outputs.

Accordingly, when an external disturbance occurs, the PD-I power control, wherein a power ratio is multiplied only by the I operation output and this multiplied value is added to the P and D operation outputs, renders the wafer to experience substantially identical temperature profiles, thereby providing better reproducibility of the temperature profile. With the improved reproducibility of the temperature profile, variations of thermal budgets between batches of thermally processed wafers can be decreased, enabling substantially consistent characteristics to be obtained from the films formed on different wafers.

Further it can be seen from FIG. 7 that better temperature response and more stabilized temperature profiles are obtained by using the PID power control scheme when there is no external disturbance, i.e., during the ramp-up and wafer processing stages. Therefore, reliable and reproducible temperature control can be accomplished by employing the PID power ratio control scheme when there is no external disturbance and the PD-I power ratio control scheme if otherwise.

Further, when performing power ratio control in controlling temperatures, a power ratio multiplied by the I operation output can be set to be different from that multiplied by the P and D operation outputs, e.g., by employing appropriate different weighting factors thereto. It is also possible to employ PID power ratio control scheme even when there occurs an external disturbance. In that case, a power ratio multiplied by the I operation output is preferably set to be greater than that for the P and D operation outputs by applying a weighting factor to the power ratio for the I operation output, which is greater than that for the P and D operation outputs.

Referring to FIG. 8, there are depicted two sets of measured temperature profiles obtained by using target temperatures and measured temperatures as the control temperatures being employed for the selection of power ratio tables. In FIG. 8, a dotted line S represents a predetermined target temperature profile; reference signs C1 and C2, two measured temperature profiles at the center zone when the target temperatures are used as the control temperatures; and reference signs D1 and D2, two measured temperature profiles at the center zone when measured temperatures are used as the control temperatures.

As is apparent from FIG. 8, in the presence of an external disturbance, an improved temperature reproducibility can be obtained when the target temperatures are used as the control temperatures, while setting the measured temperatures as the control temperatures renders the temperature response faster and improves the temperature stability when there exists no or little external disturbances.

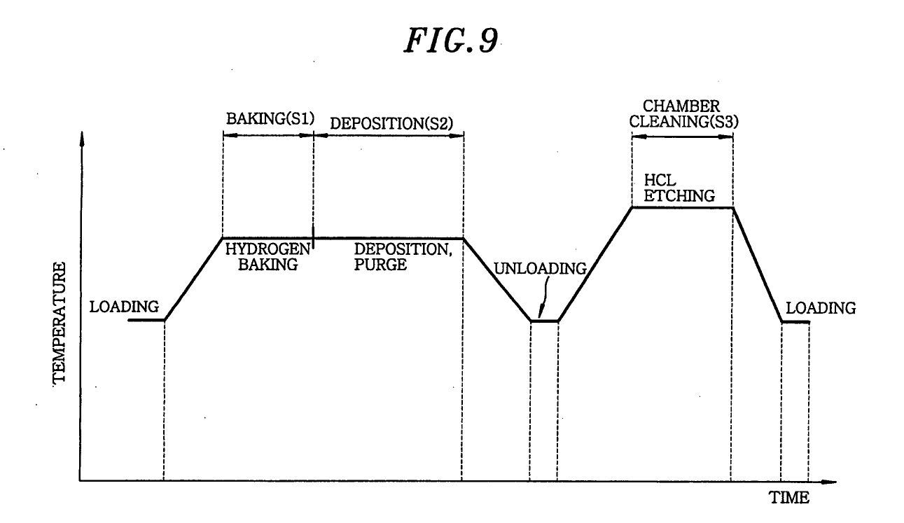

In the preferred embodiments described above, there have been presented temperature control processes from a wafer loading stage to a wafer unloading stage in the single wafer epitaxial growth apparatus of the present invention. FIG. 9 presents an exemplary overall process which can be carried out in the single wafer epitaxial growth apparatus of the present invention. FIGS. 7 and 8 illustrate a baking stage (S1), a deposition stage (S2) and a wafer unloading stage of the overall process shown in FIG. 9. As presented in FIG. 9, the overall process in the apparatus may further include a chamber cleaning stage (S3).

As exemplified in FIG. 9, a wafer is loaded into the reaction chamber controlled to be at a loading temperature. The loading temperature has an upper limit determined in consideration of the thermal resistance of a wafer carrier and slip generation which might occur in the wafer due to a thermal shock. Subsequently, the wafer is heated upto about 1130° C. and a hydrogen baking is carried out to remove an oxide layer and defects from a surface of the wafer. Thereafter, Si epitaxy is performed on the surface of the wafer by CVD using, e.g., trichlorosilane. After depositing a Si epitaxial layer, the reaction chamber is purged with, e.g., a N₂ gas; and the wafer is cooled down to a predetermined unloading temperature and unloaded.

At the subsequent chamber cleaning stage, the reaction chamber is heated to a predetermined elevated temperature to thereby clean impurities deposited on the surface of the susceptor and on the inner wall of the reaction chamber by flowing a HCl gas therethrough. The HCl gas cleaning process is normally carried out for every one to five epitaxial growth processes depending on the overall thickness of corresponding epitaxially grown films. These processes are repeated to produce epitaxially grown wafers to be used as various semiconductor devices.

It should be apparent to those skilled in the art that the temperature controlling method of the invention can be employed in any device fabrication steps, including but not limited to etching, deposition, diffusion, annealing, surface cleaning, oxidation, ramp-up/down and doping, which requires precise temperature control of a substrate. Further, it is to be understood that the inventive temperature controlling method can also be employed in controlling temperatures of a reaction chamber, e.g., loading, unloading and chamber cleaning temperatures.

While the present invention has been described with respect to certain preferred embodiments only, other modifications and variations may be made without departing from the spirit and scope of the present invention as set forth in the following claims.

1. A method for controlling temperatures in a semiconductor manufacturing apparatus including a reaction chamber and a plurality of heating sources, comprising the steps of:
determining a set of power ratios to be fed to the heating sources for each of at least one selected temperature by using plural temperature sensors; and
controlling a given temperature by performing power control on the heating sources based on at least one set of power ratios obtained in the determining step by using one or more temperature sensors, and said temperature controlling step is carried out by using a P(proportional), an I(integral) and a D(derivative) operation outputs and power ratios corresponding to the given temperature, the power ratios corresponding to the given temperature being determined based on one or two sets of power ratios determined in the determining step, and wherein a controlled power output for a heating source is determined by multiplying the P, the D and the I operation outputs by a power ratio during processing a wafer and is determined by multiplying the power ratio only by the I operation output when loading a wafer into the reaction chamber.

2. A method for controlling temperatures in a semiconductor manufacturing apparatus including a reaction chamber and a plurality of heating sources, comprising the steps of:
determining a set of power ratios to be fed to the heating sources for each of at least one selected temperature by using plural temperature sensors; and
controlling a given temperature by performing power control on the heating sources based on at least one set of power ratios obtained in the determining step by using one or more temperature sensors, wherein the number of temperature sensors used in the determining step is greater than the number of temperature sensors used in the controlling step, and wherein the set of power ratio, based on which the power control is performed, is changed at an estimated time of reaching a target temperature.

3. A method for controlling temperatures in a semiconductor manufacturing apparatus including a reaction chamber and a plurality of heating sources, comprising the steps of:
determining a set of power ratios to be fed to the heating sources for each of at least one selected temperature by using plural temperature sensors; and
controlling a given temperature by performing power control on the heating sources based on at least one set of power ratios obtained in the determining step by using one or more temperature sensors, wherein the number of temperature sensors used in the determining step is greater than the number of temperature sensors used in the controlling step, and wherein the set of power ratio, based on which the power control is performed, is changed at an estimated time of reaching a target temperature when loading a wafer into the reaction chamber, while the set of power ratio, based on which the power control is performed, is changed at a time when a measured temperature reaches the target temperature during processing a wafer.
